(19) United States
(12) Patent Application Publication
(10) Pub. No.: US 2025/0386493 A1
(43) Pub. Date: Dec. 18, 2025

(54) METHOD FOR MANUFACTURING MEMORY DEVICE

(71) Applicant: United Microelectronics Corp., Hsinchu (TW)

(72) Inventors: Hung-Hsun SHUAI, Tainan City (TW); Jyun-Bao Yang, Tainan City (TW); Wei-Shiang Huang, Taichung City (TW); Yu-Jen Yeh, Taichung City (TW); Chih-Jung Chen, Hsinchu County (TW); Ko-Chi Chen, Hsinchu City (TW)

(21) Appl. No.: 18/795,231

(22) Filed: Aug. 6, 2024

(30) Foreign Application Priority Data
Jun. 14, 2024 (TW) 113122190

(51) Int. Cl. H10B 41/30

(52) U.S. Cl. CPC H10B 41/30

(57) ABSTRACT

A method for manufacturing a memory device includes the following steps: providing a substrate having a top surface; forming a first insulating film on the top surface of the substrate; and forming a floating gate on the first insulating film. The floating gate includes a tip structure adjacent to the first insulating film.

This application claims the benefit of Taiwan application Serial No. 113122190, filed Jun. 14, 2024, the subject matter of which is incorporated herein by reference.

### BACKGROUND OF THE INVENTION

### Field of the Invention

The invention relates in general to a method for manufacturing a semiconductor device, and more particularly to a method for manufacturing a memory device.

### Description of the Related Art

Recently, the demands for a memory device are increased. The memory device is a storage device that can read stored data when needed. In general, the memory device includes RAM (Random Access Memory) and ROM (Read Only Memory). RAM is a volatile memory device, and the stored information is lost when power is turned off; ROM is a nonvolatile memory device, and the stored information can be retained even when power is turned off. The nonvolatile memory device includes OTP (One-Time-Programmable embedded non-volatile memory) and MTP (Multiple-Times-Programmable embedded non-volatile memory). OTP can be programmed only one time for data security. For example, anti-fuse memory device is OTP. MTP can be programmed multiple times. For example, EPROM (Erasable Programmable ROM), EEPROM (Electrically EPROM) and NAND/NOR flash memory are MTPs. However, there is still an urgent need to improve the operation efficiency for OTPs and MTPs.

### SUMMARY OF THE INVENTION

The invention is directed to a method for manufacturing a memory device, and an operation efficiency of the memory device can be improved.

According to an embodiment of the present invention, a method for manufacturing a memory device is provided. The method includes the following steps: providing a substrate having a top surface; forming a first insulating film on the top surface of the substrate; and forming a floating gate on the first insulating film. The floating gate includes a tip structure adjacent to the first insulating film.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIGS. 1A-1F illustrate a method for manufacturing a memory device according to an embodiment of the present application.

FIGS. 2A-2F illustrate a method for manufacturing a memory device according to another embodiment of the present application.

FIGS. 3A-3F illustrate a method for manufacturing a tip structure according to an embodiment of the present application.

FIG. 4 illustrates a cross-sectional view of a floating gate according to an embodiment of the present invention.

FIG. 5 illustrates a cross-sectional view of a memory device according to an embodiment of the present invention.

FIG. 6 illustrates a cross-sectional view of a memory device according to another embodiment of the present invention.

FIG. 7 is a cross-sectional view of a memory device according to a further embodiment of the present invention.

### DETAILED DESCRIPTION OF THE INVENTION

The following is illustrated with some examples. It should be noted that the present invention does not show all possible embodiments, and other implementation aspects not proposed in the present invention may also be applicable. Furthermore, the size ratios in the drawings are not drawn to the same proportions as the actual product. Therefore, the description and drawings are only used to describe the embodiments and are not used to limit the scope of the present invention. In addition, the descriptions in the embodiments, such as detailed structures, material applications, etc., are only for illustration and do not limit the scope of the present invention. The structural details of the embodiments can be changed and modified according to the needs of the actual application process without departing from the spirit and scope of the invention. The following description uses the same/similar symbols to indicate the same/similar components. It is understood that elements and features of one embodiment may be advantageously incorporated into another embodiment without further recitation.

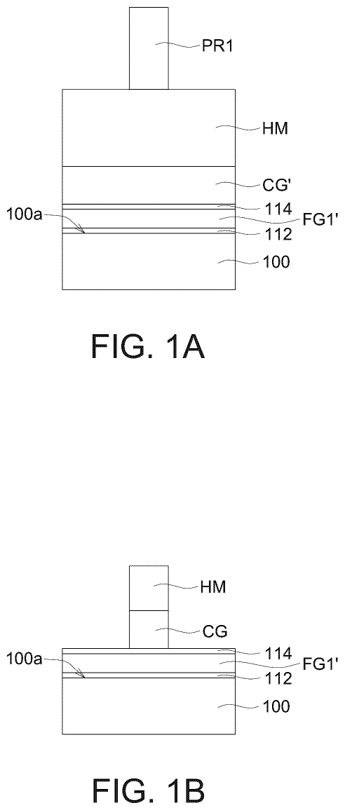

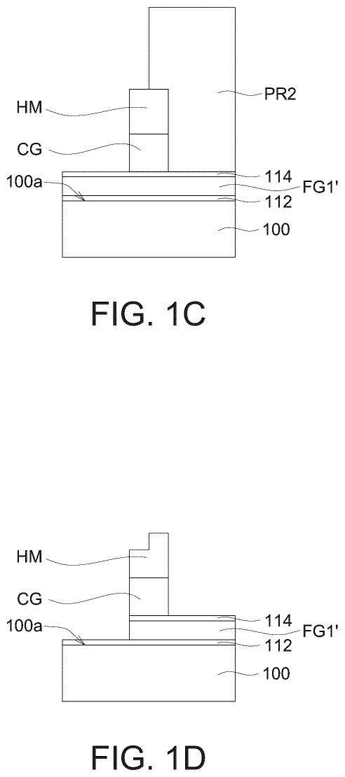

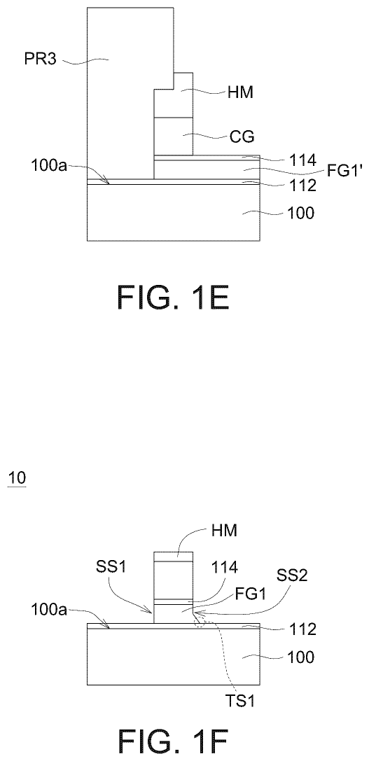

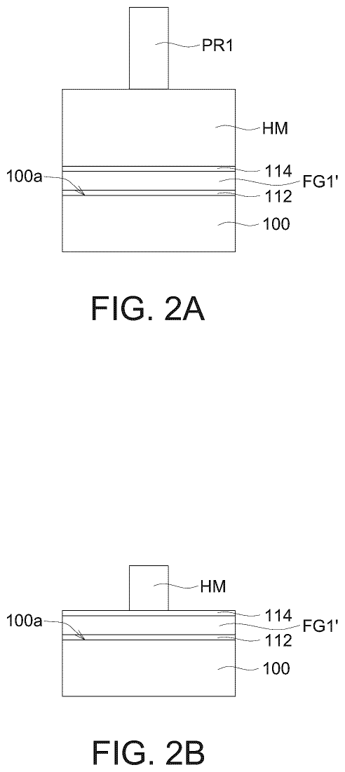

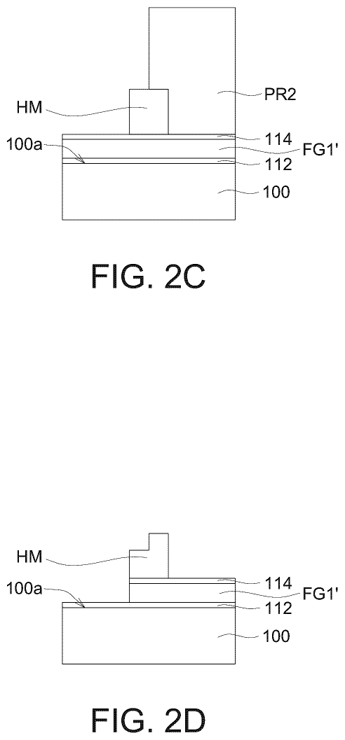

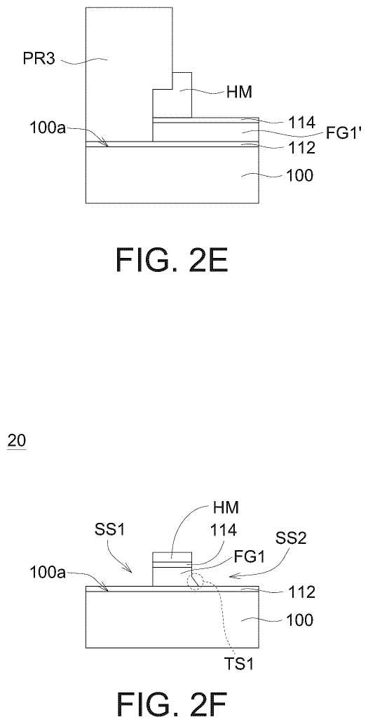

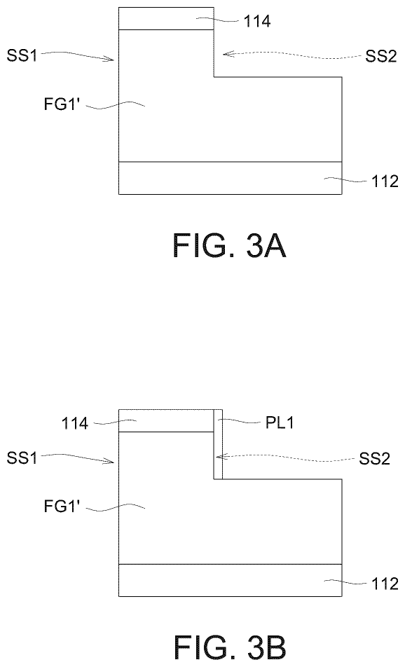

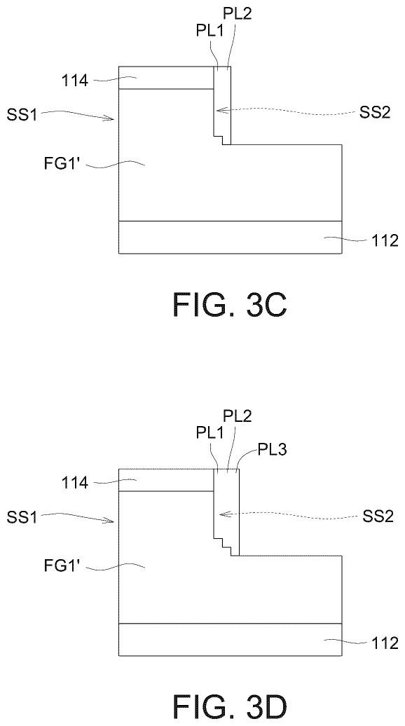

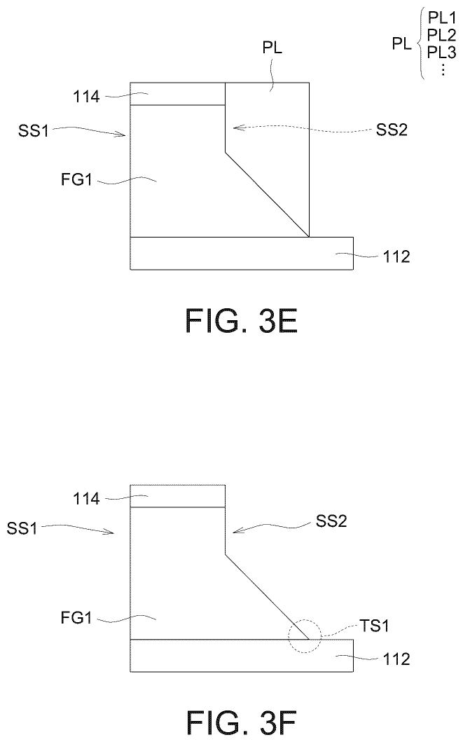

FIGS. 1A-1F illustrate a method for manufacturing a memory device 10 according to an embodiment of the present invention. That is, the method for manufacturing the memory device 10 may include the steps as shown in FIGS. 1A to 1F in sequence. FIGS. 2A to 2F illustrate a method for manufacturing a memory device 20 according to another embodiment of the present invention. That is, the method for manufacturing the memory device 20 may include the steps as shown in FIGS. 2A to 2F in sequence. FIGS. 3A to 3F illustrate a method for manufacturing a tip structure TS1 of the memory device 10 or 20 according to an embodiment of the present invention.

Referring to FIG. 1A, a substrate 100 having a top surface 100a is provided. A first insulating film 112, a first semiconductor material layer FG1′, a second insulating film 114, a second semiconductor material layer CG′ and a hard mask HM are sequentially formed on the top surface 100a of the substrate 100. Then, a photoresist layer is formed on the hard mask HM, and the photoresist layer is patterned by a lithography process to form a patterned photoresist layer PR1. The patterned photoresist layer PR1 is disposed on a middle portion of the hard mask HM, and two side portions of the hard mask HM are exposed.

In some embodiments, the materials of the first semiconductor material layer FG1′ and the second semiconductor material layer CG′ may include polycrystalline silicon. However, the materials of the first semiconductor material layer FG1′ and the second semiconductor material layer CG′ of the present invention are not limited thereto.

In some embodiments, the material of the first insulating film 112 may include an oxide, and the material of the second insulating film 114 may include an oxide. Alternatively, the second insulating film 114 may be a multi-layer structure including, for example, oxide-nitride-oxide. However, the materials of the first insulating film 112 and the second insulating film 114 of the present invention are not limited thereto.

In some embodiments, the material of the hard mask HM may include an oxide. For example, the hard mask HM may be composed of oxides. For example, the hard mask HM may include oxide and silicon nitride (SiN). However, the material of the hard mask HM of the present invention is not limited thereto.

Referring to FIG. 1B, an etching process (such as dry etching) is performed to the structure of FIG. 1A, and then the patterned photoresist layer PR1 is removed by the etching process. That is, a portion of the hard mask HM and a portion of second semiconductor material layer CG′ which are not protected by the patterned photoresist layer PR1 are removed. A remained portion of the second semiconductor material layer CG′ becomes a control gate CG.

Referring to FIG. 1C, a photoresist layer is formed on the structure of FIG. 1B, and the photoresist layer is patterned by a lithography process to form a patterned photoresist layer PR2. A portion of the hard mask HM, a portion of the control gate CG and a portion of the second insulating film 114 are exposed by the patterned photoresist layer PR2.

Referring to FIG. 1D, an etching process (such as dry etching) is performed to the structure of FIG. 1C, and then the patterned photoresist layer PR2 is removed. That is, a portion of the hard mask HM, a portion of second insulating film 114 and a portion of first semiconductor material layer FG1′ which are not protected by the patterned photoresist layer PR2 are removed.

Referring to FIG. 1E, a photoresist layer is formed on the structure of FIG. 1D, and the photoresist layer is patterned by a lithography process to form a patterned photoresist layer PR3. A portion of the hard mask HM, a portion of the control gate CG and a portion of the second insulating film 114 are exposed by the patterned photoresist layer PR3.

Referring to FIG. 1F, an etching process (such as dry etching) is performed to the structure of FIG. 1E, and then the patterned photoresist layer PR3 is removed. That is, a portion of the hard mask HM, a portion of the second insulating film 114 and a portion of the first semiconductor material layer FG1′ which are not protected by the patterned photoresist layer PR3 are removed by the etching process. A remained portion of the first semiconductor material layer FG1′ becomes a floating gate FG1. In this way, the memory device 10 is formed.

As shown in FIG. 1F, the memory device 10 includes a substrate 100 and a first insulating film 112, a floating gate FG1, a second insulating film 114, a control gate CG and a hard mask HM sequentially stacked on the top surface 100a of the substrate 100. The floating gate FG1 comprises a tip structure TS1 adjacent to the first insulating film 112. That is, the tip structure TS1 directly contacts the first insulating film 112. The floating gate FG1 further comprises a first side surface SS1 and a second side surface SS2 opposite to the first side surface SS1. The first side surface SS1 and the second side surface SS2 are nonparallel to the top surface 100a of the substrate 100, and an angle formed between the second side surface SS2 and the top surface 100a of the substrate 100 is smaller than 90 degrees, so as to from the tip structure TS1. For example, the angle formed between the second side surface SS2 and the top surface 100a of the substrate 100 (i.e., the angle corresponding to the tip structure TS1) is equal to 60 degrees, 45 degrees, 30 degrees or other suitable degrees. In some embodiments, an angle formed between the first side surface SS1 and the top surface 100a of the substrate 100 is equal to 90 degrees.

According to some embodiments, in the method for manufacturing the memory device 10, the forming step of the second side surface SS2 may be performed before the forming step of the first side surface SS1 (not shown).

The method for manufacturing the memory device 20 shown in FIGS. 2A to 2F may be similar to the method for manufacturing the memory device 10 shown in FIGS. 1A to 1F. One of the differences between the methods for manufacturing the memory device 20 and the memory device 10 is that the control gate CG is not formed in the memory device 20, and other identical parts will not be described in detail.

Referring to FIG. 2A, a substrate 100 having a top surface 100a is provided. A first insulating film 112, a first semiconductor material layer FG1′, a second insulating film 114 and a hard mask HM are sequentially formed on the top surface 100a of the substrate 100. Then, a photoresist layer is formed on the hard mask HM, and the photoresist layer is patterned by a lithography process to form a patterned photoresist layer PR1. The patterned photoresist layer PR1 is disposed on a middle portion of the hard mask HM, and two side portions of the hard mask HM are exposed.

Referring to FIG. 2B, an etching process (such as dry etching) is performed to the structure of FIG. 2A, and then the patterned photoresist layer PR1 is removed. That is, a portion of the hard mask HM which is not protected by the patterned photoresist layer PR1 is removed by the etching process.

Referring to FIG. 2C, a photoresist layer is formed on the structure of FIG. 2B, and the photoresist layer is patterned by a lithography process to form a patterned photoresist layer PR2. A portion of the hard mask HM and a portion of the second insulating film 114 are exposed by the patterned photoresist layer PR2.

Referring to FIG. 2D, an etching process (such as dry etching) is performed to the structure of FIG. 2C, and then the patterned photoresist layer PR2 is removed. That is, a portion of the hard mask HM, a portion of second insulating film 114 and a portion of first semiconductor material layer FG1′ which are not protected by the patterned photoresist layer PR2 are removed.

Referring to FIG. 2E, a photoresist layer is formed on the structure of FIG. 2D, and the photoresist layer is patterned by a lithography process to form a patterned photoresist layer PR3. A portion of the hard mask HM and a portion of the second insulating film 114 are exposed by the patterned photoresist layer PR3.

Referring to FIG. 2F, an etching process (such as dry etching) is performed to the structure of FIG. 2E, and then the patterned photoresist layer PR3 is removed by the etching process. That is, a portion of the hard mask HM, a portion of the second insulating film 114 and a portion of the first semiconductor material layer FG1′ which are not protected by the patterned photoresist layer PR3 are removed. A remained portion of the first semiconductor material layer FG1′ becomes a floating gate FG1. In this way, the memory device 20 is formed.

As shown in FIG. 2F, the memory device 20 includes a substrate 100 and a first insulating film 112, a floating gate FG1, a second insulating film 114 and a hard mask HM sequentially stacked on the top surface 100a of the substrate 100. The floating gate FG1 comprises a tip structure TS1 adjacent to the first insulating film 112. That is, the tip structure TS1 directly contacts the first insulating film 112.

According to some embodiments, in the method for manufacturing the memory device 20, the forming step of the second side surface SS2 may be performed before the forming step of the first side surface SS1 (not shown).

In one embodiment, the steps for forming the tip structure TS1 of the floating gate FG1 (i.e. the steps from FIGS. 1E to 1F or the steps from FIGS. 2E to 2F) comprises the following steps as shown in FIGS. 3A-3F.

Referring to FIG. 3A, a portion of the second insulating film 114 and a first removal portion of the first semiconductor material layer FG1′ which are not protected by the patterned photoresist layer PR3 are removed. In the present embodiment, the first removal portion of the first semiconductor material layer FG1′ corresponding to the second side surface SS2 is removed by using a first gas. The first gas is an etching gas, such as Cl₂.

Referring to FIG. 3B, the step of forming the tip structure TS1 comprises using the first gas and a second gas different from the first gas. The first gas removes a second removal portion of the first semiconductor material layer FG1′ corresponding to the second side surface SS2 (adjacent to the first removal portion), and the second gas forms a first polymer portion PL1 on the first semiconductor material layer FG1′ corresponding to the second side surface SS2. The second gas may be CH₃F or other suitable gas. The first polymer portion on the first semiconductor material layer FG1′ can protect a sidewall of the first semiconductor material layer FG1′ from being removed by the first gas.

Referring to FIG. 3C, a third removal portion of the first semiconductor material layer FG1′ corresponding to the second side surface SS2 (adjacent to the second removal portion) is removed by using the first gas and the second gas forms a second polymer portion PL2 on the first semiconductor material layer FG1′ corresponding to the second side surface SS2 (adjacent to the first polymer portion PL1).

Referring to FIG. 3D, a fourth removal portion of the first semiconductor material layer FG1′ corresponding to the second side surface SS2 (adjacent to the third removal portion) is removed by using the first gas and the second gas forms a third polymer portion PL3 on the first semiconductor material layer FG1′ corresponding to the second side surface SS2 (adjacent to the second polymer portion PL2).

Referring to FIG. 3E, as the first gas and the second gas continue to be provided, the removal portions (adjacent to each other) of the first semiconductor material layer FG1′ corresponding to the second side surface SS2 are removed by the first gas, and polymer portions PL (adjacent to each other) on the first semiconductor material layer FG1′ corresponding to the second side surface SS2 are formed by the second gas.

Referring to FIG. 3F, polymer portions PL on the first semiconductor material layer FG1′ corresponding to the second side surface SS2 adjacent to each other are removed, so as to form the floating gate FG having a tip structure TS1, and the second side surface SS2 of the floating gate FG1 is exposed. That is, a remained portion of the first semiconductor material layer FG1′ becomes the floating gate FG1. The floating gate FG1 has a first side surface SS1 and a second side surface SS2. In one embodiment, the polymer portions PL can be removed by an O₂ flush.

According to some embodiments, the first side surface SS1 and the second side surface SS2 of the floating gate FG1 are formed by patterning the first semiconductor material layer FG1′ through different etching processes. For example, the first side surface SS1 is formed by the etching process as shown in FIGS. 1C-1D or 2C-2D; the second side surface SS2 is formed by the etching process as shown in FIGS. 1E-1F or 2E-2F (i.e. including the processes as shown in FIGS. 3A-3F).

According to some embodiments, the second side surface SS2 of the floating gate FG1 has two different slopes. For example, a portion of the second side surface SS2 is perpendicular to the top surface 100a and has no slope, and the other portion of the second side surface SS2 has a slope greater than 0, as shown in FIGS. 1F, 2F and 3F, but the invention is not limited thereto.

In some embodiments, the process of forming the second side surface SS2 may also include using a third gas and/or other suitable gases. The third gas may be different from the first gas and the second gas. The third gas is, for example, helium dioxide gas (HeO₂), but the invention is not limited thereto.

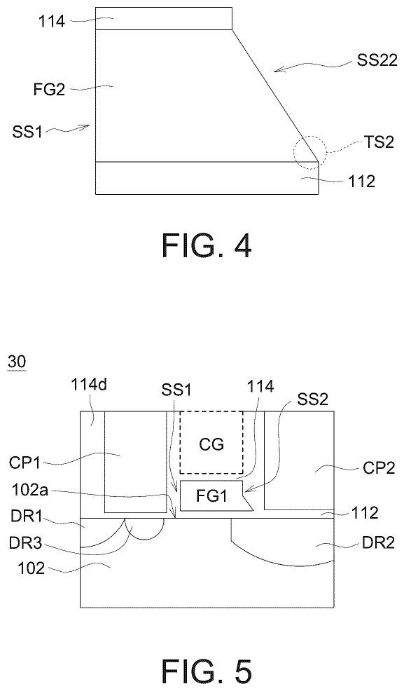

According to some embodiments, the second side surface SS2 of the floating gate FG1 may have the same slope (as shown in FIG. 4). Please refer to FIG. 4, which illustrates a cross-sectional view of the floating gate FG2 according to an embodiment of the present invention. One of the differences between the floating gate FG2 and the floating gate FG1 is that the appearance of the second side surface SS22 is different from the appearance of the second side surface SS2 (that is, the change of the slope is different), and other identical parts will not described in detail. The formation method of the second side surface SS22 is similar to the formation method of the second side surface SS2. By using the first gas and the second gas, the second side surface SS22 with a slope greater than 0 can be formed.

FIG. 5 illustrates a cross-sectional view of a memory device 30 according to an embodiment of the present invention. As shown in FIG. 5, the memory device 30 may or may not include a control gate CG. When the memory device 30 includes the control gate CG, the steps of forming the memory device 30 may include the steps as shown in FIGS. 1A to 1F. When the memory device 30 does not include the control gate CG, the steps of forming the memory device 30 may include the steps as shown in FIGS. 2A to 2F. In some embodiments, floating gate FG1 in memory device 30 may be replaced by floating gate FG2 as shown in FIG. 4.

Referring to FIG. 5, the forming step of the memory device 30 further includes forming a first conductive pillar CP1 and a second conductive pillar CP2 respectively corresponding to the first side surface SS1 and the second side surface SS2, wherein the conductive pillar CP1 and a second conductive pillar CP2 are disposed on the first insulating film 112. The upper surface of the floating gate FG1 may be covered by the second insulating film 114. The first side surface SS1, the second side surface SS2 and the sidewalls of the first conductive pillar CP1 and the second conductive pillar CP2 may be covered by the insulating layer 114d. According to some embodiments, the material of the insulating layer 114d may be the same as the material of the first insulating film 112 and the second insulating film 114. In some embodiments, the forming step of the memory device 30 further includes forming a first doped region DR1 and a second doped region DR2 respectively corresponding to the first conductive pillar CP1 and the second conductive pillar CP2 in the substrate 102. That is, in the normal direction of the top surface 102a of the substrate 102, the first conductive pillar CP1 may overlap the first doped region DR1, and the second conductive pillar CP2 may overlap the second doped region DR2. The first doped region DR1 and the second doped region DR2 have the first conductivity type. In some embodiments, the forming step of the memory device 30 further includes forming a third doped region DR3 in the substrate 102 adjacent to the first doped region DR1. The third doped region DR3 may be disposed between the first doped region DR1 and the second doped region DR2. The third doped region DR3 has the second conductivity type. The first conductivity type is, for example, N-type. The second conductivity type is, for example, P-type. For example, the first doped region DR1 and the second doped region DR2 may be heavily doped regions with N-type dopants. The third doped region DR3 may be a P-type lightly doped region. The first doped region DR1 and the second doped region DR2 can serve as a bit line (BL) and a source line (SL) respectively. The first conductive pillar CP1 can serve as a word line (WL). The second conductive pillar CP2 can serve as an erase gate (EG). In some embodiments, the steps for forming the memory device 30 further include forming other doped regions in the substrate 102.

According to some embodiments, the substrate 102 may be a P-type semiconductor substrate, and the materials of the first conductive pillar CP1 and the second conductive pillar CP2 may include polycrystalline silicon. Alternatively, the material of the second conductive pillar CP2 may include metal.

According to some embodiments, the memory device 30 can be applied to multiple-times-programmable embedded non-volatile memory (MTP), for example, can be applied to NOR flash or NAND flash.

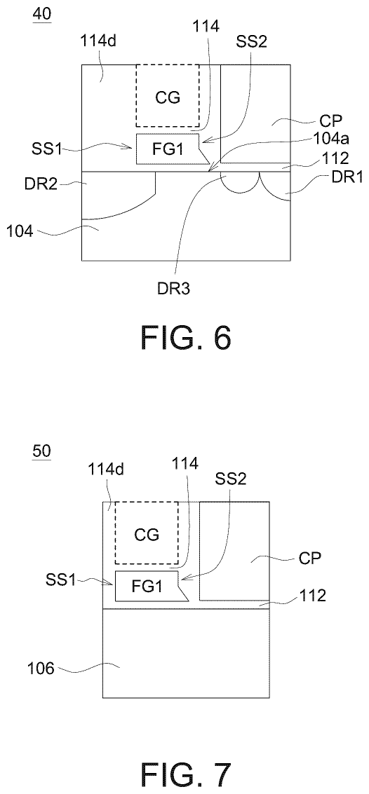

FIG. 6 illustrates a cross-sectional view of a memory device 40 according to another embodiment of the present invention. As shown in FIG. 6, the memory device 40 may or may not include a control gate CG. When the memory device 40 includes the control gate CG, the steps of forming the memory device 40 may include the steps as shown in FIGS. 1A to 1F. When the memory device 40 does not include the control gate CG, the steps of forming the memory device 40 may include the steps as shown in FIGS. 2A to 2F. In some embodiments, the floating gate FG1 in memory device 40 may be replaced by the floating gate FG2 as shown in FIG. 4.

Referring to FIG. 6, the forming steps of the memory device 40 further includes forming a conductive pillar CP on the first insulating film 112 and adjacent to the tip structure TS1. The conductive pillar CP is disposed on the first insulating film 112. The upper surface of the floating gate FG1 may be covered by the second insulating film 114. The first side surface SS1, the second side surface SS2 and the sidewalls of the conductive pillar CP may be covered by the insulating layer 114d. According to some embodiments, the material of the insulating layer 114d may be the same as the material of the first insulating film 112 and the second insulating film 114. In some embodiments, the forming steps of the memory device 40 further includes forming a first doped region DR1 and a second doped region DR2 respectively corresponding to the conductive pillar CP and the first side surface SS1 in the substrate 104. That is, in the normal direction of the top surface 104a of the substrate 104, the conductive pillar CP may overlap the first doped region DR1, and the first side surface SS1 may overlap the second doped region DR2. The first doped region DR1 and the second doped region DR2 have the first conductivity type. In some embodiments, the forming steps of the memory device 40 further includes forming a third doped region DR3 in the substrate 104 adjacent to the first doped region DR1. The third doped region DR3 may be disposed between the first doped region DR1 and the second doped region DR2. The third doped region DR3 has the second conductivity type. The first conductivity type is, for example, N-type. The second conductivity type is, for example, P-type. For example, the first doped region DR1 and the second doped region DR2 may be heavily doped regions with N-type dopants. The third doped region DR3 may be a P-type lightly doped region. The first doped region DR1 and the second doped region DR2 may serve as bit lines (BL) and source lines (SL) respectively. The conductive pillar CP1 may serve as a bit line (WL), an erase gate (EG) or a selection gate (SG). In some embodiments, forming the memory device 40 further includes forming additional doped regions in the substrate 104.

According to some embodiments, the substrate 104 may be a P-type semiconductor substrate. The material of the conductive pillar CP may include polycrystalline silicon. Alternatively, the material of the conductive pillar CP may include metal.

According to some embodiments, the memory device 40 can be applied to multiple-times-programmable embedded non-volatile memory (MTP), such as NOR flash or NAND flash.

FIG. 7 illustrates a cross-sectional view of a memory device 50 according to a further embodiment of the present invention. As shown in FIG. 7, the memory device 50 may or may not include a control gate CG. When the memory device 50 includes the control gate CG, the steps of forming the memory device 50 may include the steps shown in FIGS. 1A to 1F. When the memory device 50 does not include the control gate CG, the steps of forming the memory device 50 may include the steps shown in FIGS. 2A to 2F. In some embodiments, the floating gate FG1 in memory device 50 may be replaced by the floating gate FG2 as shown in FIG. 4. One of the differences between the memory device 50 and the memory device 40 is that the substrate 106 of the memory device 50 may not include the first doped region DR1 to the third doped region DR3 as shown in FIG. 6.

Referring to FIG. 7, the forming steps of the memory device 50 further includes forming a conductive pillar CP on the first insulating film 112 and adjacent to the tip structure TS1. The conductive pillar CP is disposed on the first insulating film 112. The upper surface of the floating gate FG1 may be covered by the second insulating film 114. The first side surface SS1, the second side surface SS2 and the sidewalls of the conductive pillar CP may be covered by the insulating layer 114d. According to some embodiments, the material of the insulating layer 114d may be the same as the materials of the first insulating film 112 and the second insulating film 114.

According to some embodiments, the substrate 106 may be a P-type semiconductor substrate. The material of the conductive pillar CP may include polycrystalline silicon. Alternatively, the material of the conductive pillar CP may include metal.

According to some embodiments, the memory device 50 may be applied to a one-time-programmable embedded non-volatile memory (OTP), such as an anti-fuse memory device.

According to an embodiment of the present invention, a method for manufacturing a memory device is provided. The method includes the following steps: providing a substrate having a top surface; forming a first insulating film on the top surface of the substrate; and forming a floating gate on the first insulating film. The floating gate includes a tip structure adjacent to the first insulating film. Compared with the comparative example in which the floating gate of the memory device does not include a tip structure, since the floating gate of the memory device formed according to the manufacturing method of the present invention includes a tip structure, the tip structure of the floating gate has better electrical characteristics, and the conduction efficiency of the memory device can be improved, for example, improving the operating efficiency of the memory device.

While the invention has been described by way of example and in terms of the preferred embodiment(s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A method for manufacturing a memory device, comprising:
providing a substrate having a top surface;
forming a first insulating film on the top surface of the substrate; and
forming a floating gate on the first insulating film, wherein the floating gate comprises a tip structure adjacent to the first insulating film.

2. The method according to claim 1, wherein the floating gate further comprises a first side surface and a second side surface opposite to the first side surface, and the first side surface and the second side surface are nonparallel to the top surface of the substrate, and an angle formed between the second side surface and the top surface of the substrate is smaller than 90 degrees, so as to from the tip structure.

3. The method according to claim 2, wherein an angle formed between the first side surface and the top surface of the substrate is equal to 90 degrees.

4. The method according to claim 2, wherein the step of forming the tip structure comprises using a first gas and a second gas different from the first gas.

5. The method according to claim 4, wherein the step of forming the tip structure further comprises:
forming a first semiconductor material layer on the first insulating film;
pattering the first semiconductor material layer to form the first side surface and the second side surface by different etching processes, wherein the first gas removes removal portions of the first semiconductor material layer corresponding to the second side surface, and the second gas forms polymer portions on the first semiconductor material layer corresponding to the second side surface; and
removing the polymer portions to expose the second side surface.

6. The method according to claim 5, wherein the first gas is Cl₂.

7. The method according to claim 5, wherein the second gas is CH₃F.

8. The method according to claim 5, further comprises:
sequentially forming a second insulating film, a second semiconductor material layer and a hard mask on the first semiconductor material layer;
forming a photoresist layer on the hard mask;
pattering the photoresist layer to form a patterned photoresist layer; and
removing a portion of the hard mask and a portion of second semiconductor material layer which are not protected by the patterned photoresist layer, and a remained portion of the second semiconductor material layer becomes a control gate.

9. The method according to claim 8, further comprises forming a conductive pillar on the first insulating film and near the tip structure.

10. The method according to claim 8, further comprises forming a first conductive pillar and a second conductive pillar corresponding to the first side surface and the second side surface, respectively, wherein the first conductive pillar and the second conductive pillar are disposed on the first insulating film.
